(19) United States
(12) Patent Application Publication
(10) Pub. No.: US 2025/0336794 A1
(43) Pub. Date: Oct. 30, 2025

(54) PACKAGE SUBSTRATE AND MANUFACTURING METHOD THEREOF

(71) Applicant: SILICONWARE PRECISION INDUSTRIES CO., LTD., Taichung City (TW)

(72) Inventors: Pao-Hung TSENG, Taichung City (TW); Yu-Cheng PAI, Taichung City (TW); Yuan-Ping YEH, Taichung City (TW)

(73) Assignee: SILICONWARE PRECISION INDUSTRIES CO., LTD., Taichung City (TW)

(21) Appl. No.: 18/894,595

(22) Filed: Sep. 24, 2024

(30) Foreign Application Priority Data
Apr. 30, 2024 (TW) 113116198

(51) Int. Cl. H01L 23/498; H01L 21/48

(52) U.S. Cl. CPC H01L 23/49838; H01L 21/4857; H01L 23/49822

(57) ABSTRACT

A package substrate is provided, which includes an insulating protective layer formed on a circuit structure, wherein circuit structure includes an insulating layer and a first circuit layer bonded to the insulating layer, and the insulating layer has at least one recessed portion, so that the insulating protective layer is bonded to a bonding layer formed in the recessed portion, or the insulating protective layer is received in the recessed portion and protruded from the recessed portion. Therefore, when the insulating protective layer is designed as NSMD, the portions around the openings will not be disposed on the surface of the insulating layer to avoid excessive undercut structures in the insulating protective layer. Also provided is a manufacturing method for the package substrate.

### BACKGROUND

### 1. Technical Field

The present disclosure relates to a semiconductor manufacturing process, and more particularly, to a package substrate and a manufacturing method thereof.

### 2. Description of Related Art

With the vigorous development of the electronics industry, electronic products tend to be thin, light, short and small in form, and in the direction of high performance, high functionality and high speed in terms of function. Therefore, in order to meet the high integration and miniaturization requirements of semiconductor devices, package substrates having high-density and fine-pitch circuits are often used in the packaging process.

FIG. 1 is a schematic cross-sectional view of a conventional package substrate 1.

As shown in FIG. 1, a first circuit layer 11 embedded in a dielectric layer 10 and a second circuit layer 12 formed on the dielectric layer 10 are formed on two opposite surfaces of a dielectric layer 10, wherein at least one conductive blind hole 100 electrically connected to the first circuit layer 11 and the second circuit layer 12 is formed in the dielectric layer 10, and a solder mask layer 13 such as green paint is formed on the opposite surfaces of the dielectric layer 10, allowing partial surfaces of the first circuit layer 11 and the second circuit layer 12 are exposed from openings 130 of the solder mask layer 13 to be served as electrical contact pads.

However, in the conventional packaging substrate 1, under the design of non solder mask defined (NSMD), the green paint around the opening 130 of the solder mask layer 13 is disposed on the surface of the dielectric layer 10, thereby a larger undercut structure P is produced. Accordingly, it is easy to cause the bottom of the solder mask layer 13 to peel off, resulting in poor reliability of the package substrate 1.

Therefore, how to overcome the aforementioned problems of conventional techniques has become an urgent issue to be solved.

### SUMMARY

In view of the various deficiencies of the prior art, the present disclosure provides a package substrate, which includes: a circuit structure including an insulating layer and a first circuit layer bonded to the insulating layer, wherein the insulating layer has at least one recessed portion, and an insulating protective layer provided on the circuit structure, wherein the insulating protective layer is bonded to a bonding layer formed in the recessed portion, or the insulating protective layer is received in the recessed portion and protruded from the recessed portion.

The present disclosure further provides a method for manufacturing a package substrate, which includes: providing a circuit structure including an insulating layer and a first circuit layer bonded to the insulating layer, wherein the insulating layer has at least one recessed portion; and forming an insulating protective layer on the circuit structure, wherein the insulating protective layer is bonded to a bonding layer formed in the recessed portion, or the insulating protective layer is received in the recessed portion and protruded from the recessed portion.

In the aforementioned package substrate and the manufacturing method thereof, the circuit structure includes a core layer and a plurality of wiring layers formed on two opposite surfaces of the core layer, wherein the core layer has at least one conductive via electrically connected to the wiring layers, the insulating layer is formed on the core layer to cover the wiring layers, and the wiring layers are electrically connected to the first circuit layer.

In the aforementioned package substrate and the manufacturing method thereof, the insulating layer has a first surface and a second surface opposite to the first surface. The first circuit layer is bonded to the first surface of the insulating layer, and a second circuit layer is formed on the second surface of the insulating layer. At least one conductive blind hole electrically connected to the first circuit layer and the second circuit layer is formed in the insulating layer.

In the aforementioned package substrate and the manufacturing method thereof, the insulating protective layer has a plurality of openings, allowing a portion of the first circuit layer is exposed from the plurality of openings.

In the aforementioned package substrate and the manufacturing method thereof, the bonding layer is made of metal.

As can be seen from the above, in the package substrate and its manufacturing method of the present disclosure, the insulating protective layer is bonded to the bonding layer or received in the recessed portion, so that the portion around the opening is not positioned on the surface of the insulating layer when the insulating protective layer is designed with non-solder mask definition (NSMD). Therefore, no excessive undercut structure will be produced. Therefore, compared with the prior art, the present disclosure can avoid the problem of peeling off from taking place at the bottom of the insulating protective layer, thereby improving the reliability of the package substrate.

### BRIEF DESCRIPTION OF THE DRAWINGS

FIG. 1 is a schematic cross-sectional view of a conventional package substrate.

FIG. 2A to FIG. 2D are schematic cross-sectional views illustrating a manufacturing method of a package substrate according to a first embodiment of the present disclosure.

FIG. 3A to FIG. 3B are schematic cross-sectional views according to another embodiment of FIG. 2B to FIG. 2D.

FIG. 4A to FIG. 4C are schematic cross-sectional views illustrating a manufacturing method of a package substrate according to a second embodiment of the present disclosure.

FIG. 5A to FIG. 5B are schematic cross-sectional views according to another embodiment of FIG. 4B to FIG. 4C.

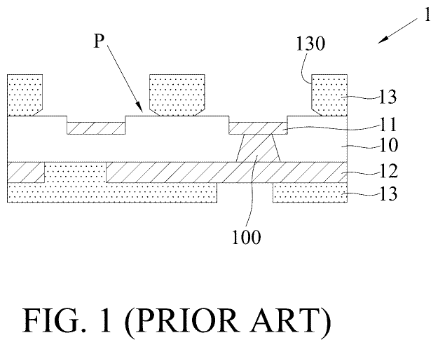

### DETAILED DESCRIPTIONS

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “one” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

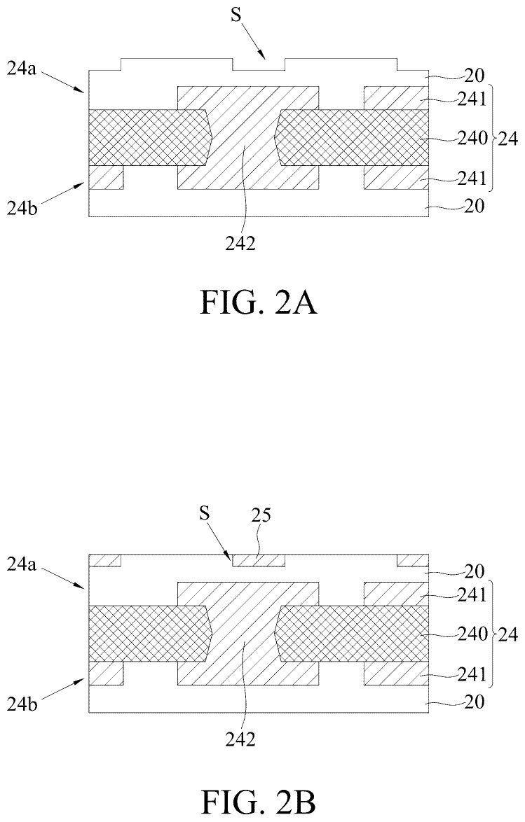

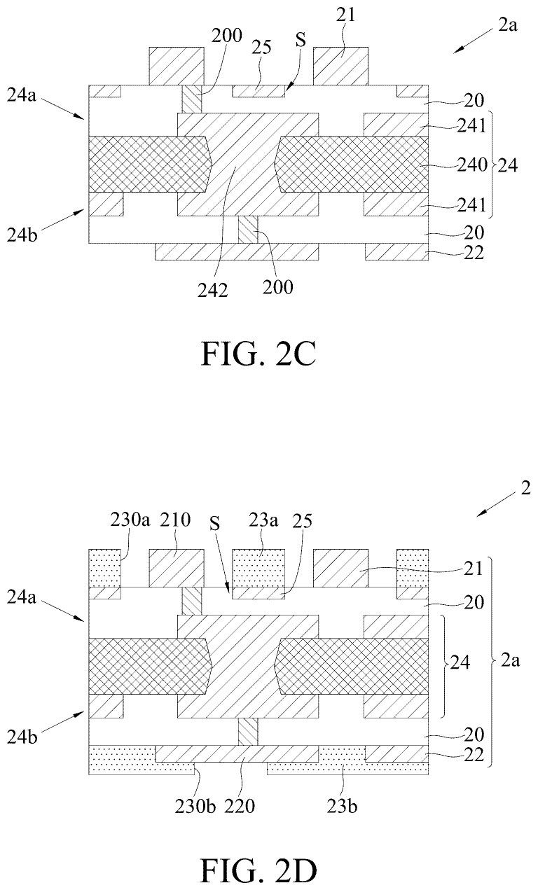

FIG. 2A to FIG. 2D are schematic cross-sectional views illustrating a manufacturing method of a packaging substrate 2 according to a first embodiment of the present disclosure.

As shown in FIG. 2A, a plate 24 has a first side 24a and a second side 24b. An insulating layer 20 is formed on the first side 24a and the second side 24b of the plate 24 respectively, and at least one recessed portion S is formed in the insulating layer 20 on the first side 24a.

In one embodiment, the plate 24 includes a core layer 240 and a plurality of wiring layers 241 formed on two opposite surfaces of the core layer 240. At least one conductive via 242 electrically connected to the wiring layers 241 is formed in the core layer 240. For example, the material for forming the wiring layer 241 and the conductive via 242 includes copper material, and the core layer 240 is made of dielectric materials such as polybenzoxazole (PBO), polyimide (PI), and prepreg (PP).

Furthermore, the insulating layer 20 is a dielectric layer, and its material for forming the insulating layer 20 is such as Ajinomoto build-up film (ABF), polybenzoxazole (PBO), polyimide (PI), and prepreg materials (PP) with glass fiber or other dielectric materials.

In addition, the insulating layer 20 is formed on the plate 24 by lamination to cover the wiring layers 241.

In addition, the recessed portions S are formed on the insulating layer 20 on the first side 24a by laser or other methods.

As shown in FIG. 2B, a bonding layer 25 is formed in the recessed portions S on the first side 24a, so that the upper surface of the bonding layer 25 is flush with the upper surface of the insulating layer 20 on the first side 24a.

In one embodiment, the bonding layer 25 is a metal material, such as a copper layer.

As shown in FIG. 2C, a first circuit layer 21 is formed on the surface of the insulating layer 20 on the first side 24a, and a second circuit layer 22 is formed on the surface of the insulating layer 20 on the second side 24b, so as to form a circuit structure 2a.

In one embodiment, the first circuit layer 21 is made of copper material and is electrically connected to the wiring layer 241. For example, the first circuit layer 21 adopts a redistribution layer (RDL) specification.

Furthermore, the second circuit layer 22 is made of copper and is electrically connected to the wiring layer 241, wherein at least one conductive blind hole 200 electrically connected to the wiring layer 241, the first circuit layer 21 and the second circuit layer 22 can be formed in the insulating layer 20. For example, the second circuit layer 22 and the conductive blind hole 200 adopt a redistribution layer (RDL) specification.

As shown in FIG. 2D, an insulating protective layer 23a such as a solder mask is formed on the bonding layer 25, and the insulating protective layer 23a has a plurality of openings 230a, so that a portion of the first circuit layer 21 is exposed from the plurality of openings 230a to be served as electrical contact pads 210.

In one embodiment, the insulating protective layer 23a uses Non solder mask defined (NSMD) to make the openings 230a of the first side 24a, so that the insulating protective layer 23a does not contact with the insulating layer 20.

Furthermore, an insulating protective layer 23b is also formed on the surface of the insulating layer 20 on the second side 24b, and the insulating protective layer 23b on the second side 24b has a plurality of openings 230b, allowing a portion of the second circuit layer 22 is exposed from the plurality of openings 230b to be served as electrical contact pads 220. For example, a solder mask definition (SMD) can be used to make the openings 230b on the second side 24b, so that the insulating protective layer 23b contacts with the insulating layer 20 to form the package substrate 2 of the present disclosure.

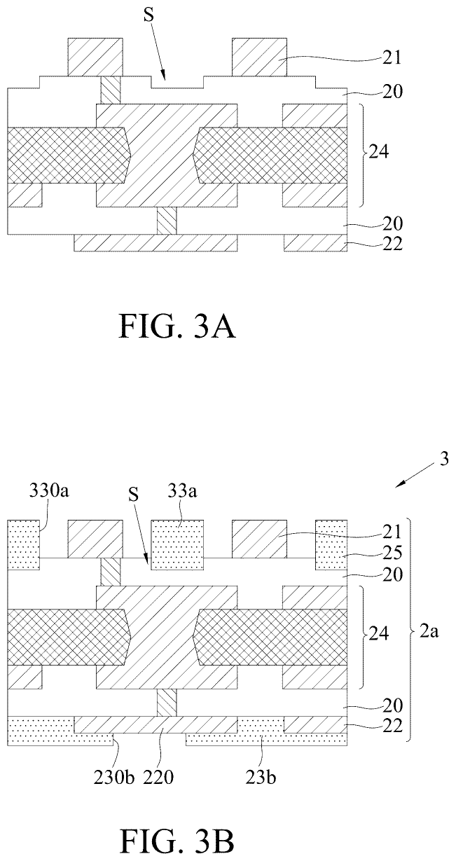

In addition, in another manufacturing method of a package substrate 3 shown in FIG. 3A to FIG. 3B, the process of manufacturing the bonding layer 25 in FIG. 2B can be omitted, thereby the insulating protective layer 33a on the first side 24a is formed in the recessed portion S and protruded from the recessed portion S and is in contact with the insulating layer 20. At the same time, the insulating protective layer 33a is formed with a plurality of openings 330a with non-solder mask definition (NSMD) specifications.

Therefore, in the first embodiment of the manufacturing method of the package substrate 2, 3 of the present disclosure, the insulating protective layer 23a, 33a is bonded to the bonding layer 25 or received in the recessed portion S depending on the design of the recessed portion S, so that the solder mask material (such as green paint) around the openings 230a and 330a is not disposed on the surface of the insulating layer 20 when the insulating protective layers 23a and 33a are designed with non-solder mask definition (NSMD). Therefore, the insulating protective layers 23a and 33a will not produce an excessively large undercut structure, or even an undercut structure. Therefore, compared with the prior art, the manufacturing method of this embodiment can effectively avoid the problem of peeling off from taking place at the bottom of the insulating protective layers 23a and 33a, thereby effectively improving the reliability of the package substrates 2 and 3.

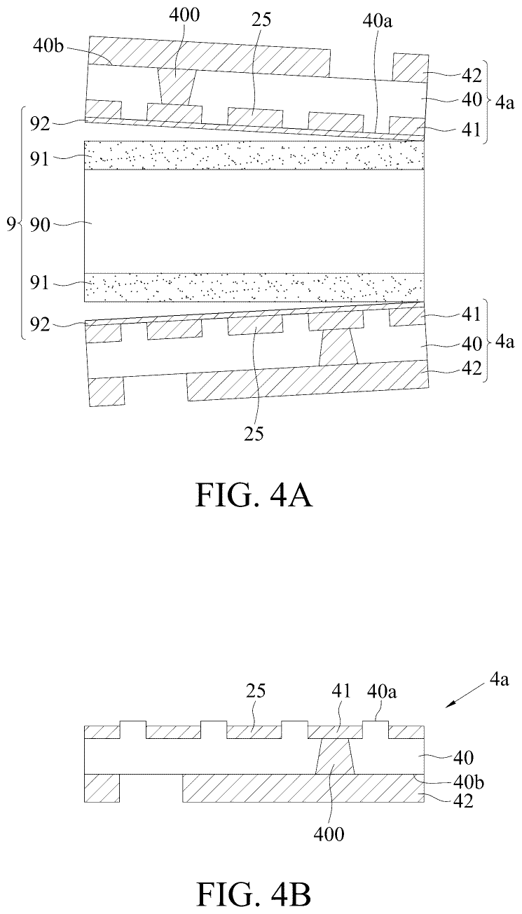

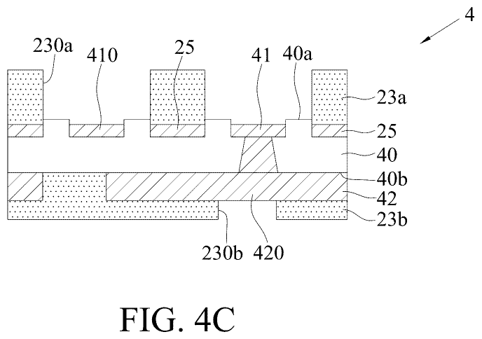

FIG. 4A to FIG. 4C are schematic cross-sectional views illustrating a method for manufacturing a package substrate 4 according to a second embodiment of the present disclosure. The difference between this embodiment and the first embodiment lies in the form of the package substrate 4 and other structures are basically the same, so the similarities will not be restated below.

As shown in FIG. 4A, a carrier member 9 is provided to form circuit structures 4a on opposite sides of the carrier member 9 respectively.

In one embodiment, the carrier member 9 is a temporary carrier board, and can be a plate with metal surfaces on opposite sides, such as a copper foil substrate, wherein the surface of a plate 90 of the carrier member 9 is provided with a release layer 91, and a metal layer 92 such as a copper layer is formed on the release layer 91, thereby the circuit structure 4a is formed on the metal layer 92.

Furthermore, the circuit structure 4a includes a first circuit layer 41 and a bonding layer 25 provided on the metal layer 92, an insulating layer 40 provided on the first circuit layer 41 and the bonding layer 25, and at least one second circuit layer 42 is formed on the insulating layer 40.

The first circuit layer 41 is made of copper, and the material for forming the first circuit layer 41 is the same as the material that forms the metal layer 92.

In one embodiment, the first circuit layer 41 and the bonding layer 25 can be formed together on the metal layer 92 by adopting redistribution layer (RDL) specifications.

The insulating layer 40 has a first surface 40a and a second surface 40b opposite to the first surface 40a, the first surface 40a is bonded to the metal layer 92, and the first circuit layer 41 is formed on the first surface 40a of the insulating layer 40.

In one embodiment, the insulating layer 40 is a dielectric layer made of a material such as Ajinomoto build-up film (ABF), polybenzoxazole (PBO), polyimide (PI), prepreg (PP) with glass fiber or other dielectric materials.

Furthermore, the insulating layer 40 is pressed onto the first circuit layer 41 and the bonding layer 25 in a pressing manner, so that the first circuit layer 41 and the bonding layer 25 are embedded in the insulating layer 40.

The second circuit layer 42 is formed on the second surface 40b of the insulating layer 40, and at least one conductive blind hole 400 electrically connected to the first circuit layer 41 and the second circuit layer 42 is formed in the insulating layer 40.

In one embodiment, the second circuit layer 42 and the conductive blind hole 400 adopt redistribution layer (RDL) specifications.

As shown in FIG. 4B, the plate 90 of the carrier member 9 and the metal layer 92 are separated by the release layer 91 (as shown in FIG. 4A). Then, the metal layer 92 is removed to obtain a plurality of circuit structures 4a.

In one embodiment, the release layer 91 is removed by peeling or other methods to separate the plate 90 from the metal layer 92, and the metal layer 92 is removed by etching.

Furthermore, the surfaces of the first circuit layer 41 and the bonding layer 25 are lower than or flush with the first surface 40a of the insulating layer 40, so that the first circuit layer 41 and the bonding layer 25 are exposed from the first surface 40a of the insulating layer 40.

As shown in FIG. 4C, an insulating protective layer 23a is formed on the bonding layer 25 to form a coreless package substrate 4, wherein the insulating protective layer 23a has a plurality of openings 230a for a portion of the first circuit layer 41 to be exposed from the plurality of openings 230a to be served as electrical contact pads 410.

In one embodiment, the insulating protective layer 23a uses non-solder mask definition (NSMD) to form the opening 230a, so that the insulating protective layer 23a is not in contact with the insulating layer 40.

Furthermore, the insulating protective layer 23b is also formed on the second surface 40b of the insulating layer 40, and the insulating protective layer 23b on the second surface 40b has a plurality of openings 230b for a portion of the second circuit layer 42 to be exposed from the plurality of openings 230b to be served as electrical contact pads 420. For example, a solder mask definition (SMD) can be used to form the openings 230b, so that the insulating protective layer 23b is in contact with the insulating layer 40.

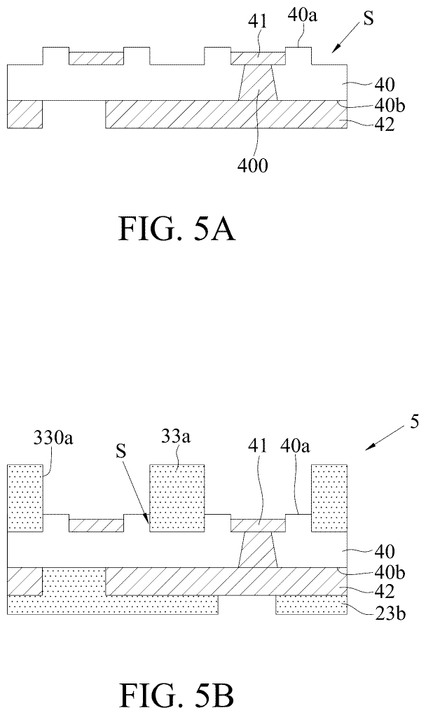

In addition, another method for manufacturing a package substrate 5 as shown in FIG. 5A to FIG. 5B, corresponding to the previous FIG. 4B, the bonding layer 25 of the circuit structure 4a can be removed first, wherein the recessed portion S is formed on the first surface 40a of the insulating layer 40, so that the insulating protective layer 33a is formed in the recessed portion S and protrudes from the recessed portion S and contacts with the insulating layer 40. At the same time, the insulating protective layer 33a is formed with a plurality of openings 330a with non-solder mask definition (NSMD) specifications.

Therefore, in the second embodiment of the manufacturing method of the package substrate 4, 5 of the present disclosure, the insulating protective layer 23a, 33a is bonded to the bonding layer 25 or received in the recessed portion S, so that the solder mask material (such as green paint) around the openings 230a and 330a is not disposed on the first surface 40a of the insulating layer 40 when the insulating protective layer 23a and 33a is designed with non-solder mask definition (NSMD). Therefore, the insulating protective layers 23a and 33a will not produce an excessively large undercut structure, or even an undercut structure. Therefore, compared with the prior art, the manufacturing method of this embodiment can effectively avoid the problem of peeling off from taking place at the bottom of the insulating protective layers 23a and 33a, thereby effectively improving the reliability of the package substrates 4 and 5.

The present disclosure also provides a package substrate 2, 3, 4, 5, which includes: a circuit structure 2a, 4a and an insulating protective layer 23a, 33a.

The circuit structure 2a, 4a is formed with an insulating layer 20, 40 and a first circuit layer 21, 41 bonded to the insulating layer 20, 40, wherein the insulating layer 20, 40 has at least one recessed portion S.

The insulating protective layer 23a, 33a is formed on the circuit structure 2a, 4a. The insulating protective layer 23a is bonded to a bonding layer 25 formed in the recessed portion S, or the insulating protective layer 33a is received in the recessed portion S and protruded from the recessed portion S.

In one embodiment, the circuit structure 2a includes a core layer 240 and a plurality of wiring layers 241 provided on two opposite surfaces of the core layer 240. The core layer 240 has at least one conductive via 242 electrically connected to the wiring layers 241, and the insulating layer 20 is formed on the core layer 240 to cover the wiring layers 241, so that the wiring layers 241 are electrically connected to the first circuit layer 21.

In one embodiment, the insulating layer 40 has a first surface 40a and a second surface 40b opposite to the first surface 40a. The first circuit layer 41 is bonded to the first surface 40a of the insulating layer 40. A second circuit layer 42 is formed on the second surface 40b of the insulating layer 40, at least one conductive blind hole 400 electrically connected to the first circuit layer 41, and the second circuit layer 42 is formed in the insulating layer 40.

In one embodiment, the insulating protective layer 23a, 33a has a plurality of openings 230a, 330a, allowing a portion of the first circuit layer 21, 41 is exposed from the plurality of openings 230a, 330a.

In one embodiment, the bonding layer 25 is made of metal.

To sum up, in the package substrate and its manufacturing method of the present disclosure, the insulating protective layer is bonded to the bonding layer or received in the recessed portion, so that the solder mask around the opening is not disposed on the surface of the insulating layer when the insulating protective layer is designed with non-solder mask definition (NSMD). Therefore, no excessive undercut structure will be produced, thereby effectively improving the reliability of the package substrate.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A package substrate, comprising:
a circuit structure comprising an insulating layer and a first circuit layer bonded to the insulating layer, wherein the insulating layer has at least one recessed portion; and
an insulating protective layer provided on the circuit structure, wherein the insulating protective layer is bonded to a bonding layer formed in the recessed portion, or the insulating protective layer is received in the recessed portion and protruded from the recessed portion.

2. The package substrate of claim 1, wherein the circuit structure comprises a core layer and a plurality of wiring layers provided on two opposite surfaces of the core layer, wherein the core layer has at least one conductive via electrically connected to the wiring layers, the insulating layer is formed on the core layer to cover the wiring layers, and the wiring layers are electrically connected to the first circuit layer.

3. The package substrate of claim 1, wherein the insulating layer has a first surface and a second surface opposite to the first surface, the first circuit layer is bonded to the first surface of the insulating layer, and a second circuit layer is formed on the second surface of the insulating layer, and wherein at least one conductive blind hole electrically connected to the first circuit layer and the second circuit layer is formed in the insulating layer.

4. The package substrate of claim 1, wherein the insulating protective layer has a plurality of openings, allowing a portion of the first circuit layer is exposed from the plurality of openings.

5. The package substrate of claim 1, wherein the bonding layer is made of metal.

6. A method for manufacturing a package substrate, comprising:
providing a circuit structure comprising an insulating layer and a first circuit layer bonded to the insulating layer, wherein the insulating layer has at least one recessed portion; and
forming an insulating protective layer on the circuit structure, wherein the insulating protective layer is bonded to a bonding layer formed in the recessed portion, or the insulating protective layer is received in the recessed portion and protruded from the recessed portion.

7. The method of claim 6, wherein the circuit structure comprises a core layer and a plurality of wiring layers provided on two opposite surfaces of the core layer, wherein the core layer has at least one conductive via electrically connected to the wiring layers, the insulating layer is formed on the core layer to cover the wiring layers, and the wiring layers are electrically connected to the first circuit layer.

8. The method of claim 6, wherein the insulating layer is defined with a first surface and a second surface opposite to the first surface, the first circuit layer is bonded to the first surface of the insulating layer, and a second circuit layer is formed on the second surface of the insulating layer, and wherein at least one conductive blind hole electrically connected to the first circuit layer and the second circuit layer is formed in the insulating layer.

9. The method of claim 6, wherein the insulating protective layer has a plurality of openings, allowing a portion of the first circuit layer is exposed from the plurality of openings.

10. The method of claim 6, wherein the bonding layer is made of metal.
